(19) United States
(12) Patent Application Publication
(10) Pub. No.: US 2026/0156902 A1
(43) Pub. Date: Jun. 4, 2026

(54) NORMALLY-OFF HEMT DEVICE WITH BIPOLAR OHMIC CONTACTS, AND MANUFACTURING METHOD THEREOF

(71) Applicant: STMicroelectronics International N.V., Geneva (CH)

(72) Inventors: Ferdinando IUCOLANO, Gravina di Catania (IT); Alessandro CHINI, Modena (IT); Aurore CONSTANT, Tours (FR); Cristina TRINGALI, Augusta (IT); Maria Eloisa CASTAGNA, Catania (IT)

(73) Assignee: STMicroelectronics International N.V., Geneva (CH)

(21) Appl. No.: 19/398,912

(22) Filed: Nov. 24, 2025

(30) Foreign Application Priority Data
Dec. 4, 2024 (IT) 102024000027471

(51) Int. Cl. H10D 64/62; H01L 23/31; H10D 30/01; H10D 30/47; H10D 62/85; H10D 64/00

(52) U.S. Cl. CPC H10D 64/62; H10D 30/015; H10D 30/475; H10D 62/8503; H10D 64/112; H10W 74/137

(57) ABSTRACT

A HEMT device comprising: a heterostructure; a gate terminal on the heterostructure; a drain terminal on the heterostructure; and a source terminal on the heterostructure. The drain terminal comprises a first conductive contact region and a first doped contact region in direct electrical contact with the first conductive contact region. The first conductive contact region is laterally interposed between the gate terminal and the first doped contact region.

### BACKGROUND

### Technical Field

The present disclosure relates to a HEMT device and to a manufacturing method thereof, in particular to a normally-off HEMT device with reduced on-state resistance degradation.

### Description of the Related Art

HEMT transistors with heterostructure are known, in particular of gallium nitride (GaN) and aluminum gallium nitride (AlGaN), at whose interface a conductive channel, in particular a two-dimensional electron gas (2DEG), may be formed. For example, HEMT transistors are appreciated for use as high-frequency switches and as power switches, by virtue of their high breakdown threshold and high electron mobility and charge carrier density of their conductive channel. Furthermore, the high current density in the conductive channel of the HEMT transistor allows a low ON-state resistance (or simply, RON) of the conductive channel to be obtained.

In known depletion-mode HEMT devices, wherein a gate electrode extends above the AlGaN/GaN heterostructure, the transistor is normally-on, since a high charge carrier density is present in the channel even in the absence of a gate voltage applied to the heterostructure.

For safety reasons and to simplify driving circuits of HEMT devices, thus favoring their use in industrial applications, enhancement-mode HEMT devices have been introduced, wherein the transistor is normally-off. Several approaches have been proposed to obtain normally-off HEMTs, such as for example HEMTs with a recessed gate or HEMTs with a doped gate or a p-GaN gate.

FIG. 1 schematically illustrates a portion of a HEMT device 1 of a type known to the Applicant, in a triaxial system of axes X, Y, Z orthogonal to each other, in a lateral sectional view on the XZ plane. In particular, the HEMT transistor 1 is a transistor with a doped gate.

The HEMT transistor 1 includes a semiconductor body 2, which in turn comprises a substrate 4, a buffer layer 6 extending on a face 4a of the substrate 4, and a heterostructure 8 extending on the buffer layer 6.

The substrate 4 is for example of silicon, or silicon carbide (SiC) or sapphire (Al₂O₃), or GaN.

The buffer layer 6 is of aluminum gallium nitride (AlGaN), or gallium nitride (GaN), either of the intrinsic or compensated type (e.g., a carbon and/or iron doping may be used to compensate for unwanted N-type impurities, present as a consequence of the manufacturing process).

The heterostructure 8 includes, in particular, a channel layer 10, extending over the buffer layer 6, and a barrier layer 12, extending over the channel layer 10. The channel layer 10 is of intrinsic gallium nitride (GaN); the barrier layer 12 is of undoped aluminum gallium nitride (AlGaN).

The HEMT transistor 1 also comprises a source electrode 14 and a drain electrode 16, both of conductive material, such as for example titanium (Ti), aluminum (Al), tantalum (Ta) or titanium nitride (TiN).

The source electrode 14 and the drain electrode 16 extend above the heterostructure 8, more precisely in electrical contact with an upper surface 12a of the barrier layer 12 without penetrating within the barrier layer 12 (in other examples it might penetrate within the barrier layer 12).

The HEMT transistor 1 also comprises a doped gate region 18, extending above the heterostructure 8, in electrical contact with the upper surface of the barrier layer 12 without penetrating within the barrier layer 12. In particular, the doped region 18 comprises a p-GaN gate region 18a and a conductive region 18b; the conductive region 18b extends on the p-GaN gate region 18a, in electrical contact with the p-GaN gate region 18a.

One of the critical issues related to GaN-based HEMT power devices concerns the use for finding a trade-off between the degradation of the R_{ON} when the device is turned-on (transition from off-state to on-state), and the breakdown voltage value in the off-state. In fact, to obtain acceptable breakdown voltage values it is necessary to compensate for the inadvertent N-type doping of GaN in the buffer layer 6 by incorporating other elements, such as iron and/or carbon. However, the presence of these elements is one of the main reasons for the degradation of the R_{ON}, because it leads to the presence of trap states in the buffer layer 6. Such trap states lead to the accumulation of negative charge in the buffer layer 6 and to the resulting depletion of the 2DEG (thus causing the degradation of the R_{ON}).

The use is therefore felt to provide a device and a manufacturing method thereof such as to overcome the drawbacks of the prior art.

### BRIEF SUMMARY

The present disclosure relates to a HEMT device and to the manufacturing method thereof, including an HEMT device comprising a semiconductor body including a substrate, a buffer layer having N-type electrical conductivity on the substrate, and a heterostructure on the buffer layer, wherein the heterostructure includes a channel layer, configured to accommodate, in use, a conductive channel of the HEMT device, and a barrier layer on the channel layer.

The HEMT device includes a first control terminal extending completely above the barrier layer and coupled to a surface of the barrier layer, a first conduction terminal extending at least in part on the barrier layer; and a second conduction terminal extending at least in part on the barrier layer. The first conduction terminal includes a first, u-shaped conductive region extending coupled to the channel layer and forming an ohmic contact with the channel layer and a second conductive region, of a semiconductor material having P-type electrical conductivity, extending completely above the barrier layer and coupled to the surface of the barrier layer and with the first conductive region. The first conductive region is interposed between the first control terminal and the second conductive region.

### BRIEF DESCRIPTION OF THE SEVERAL VIEWS OF THE DRAWINGS

For a better understanding of the present disclosure, some embodiments thereof are now described, purely by way of non-limiting example, with reference to the attached drawings, wherein:

FIG. 1 schematically illustrates, in a lateral sectional view, a portion of a HEMT according to a known embodiment;

FIG. 2 schematically illustrates, in a lateral sectional view, a portion of a HEMT according to an embodiment of the present disclosure;

FIG. 3 schematically illustrates, in a lateral sectional view, a portion of a HEMT according to another embodiment of the present disclosure;

FIG. 4 schematically illustrates, in a lateral sectional view, a portion of a HEMT according to a further embodiment of the present disclosure;

FIGS. 5A-5F illustrate manufacturing steps of the HEMT of FIG. 2, according to an embodiment of the present disclosure;

FIG. 6 schematically illustrates, in a lateral sectional view, a portion of a HEMT according to a further embodiment of the present disclosure; and

FIG. 7 schematically illustrates, in a lateral sectional view, a portion of a HEMT according to a further embodiment of the present disclosure.

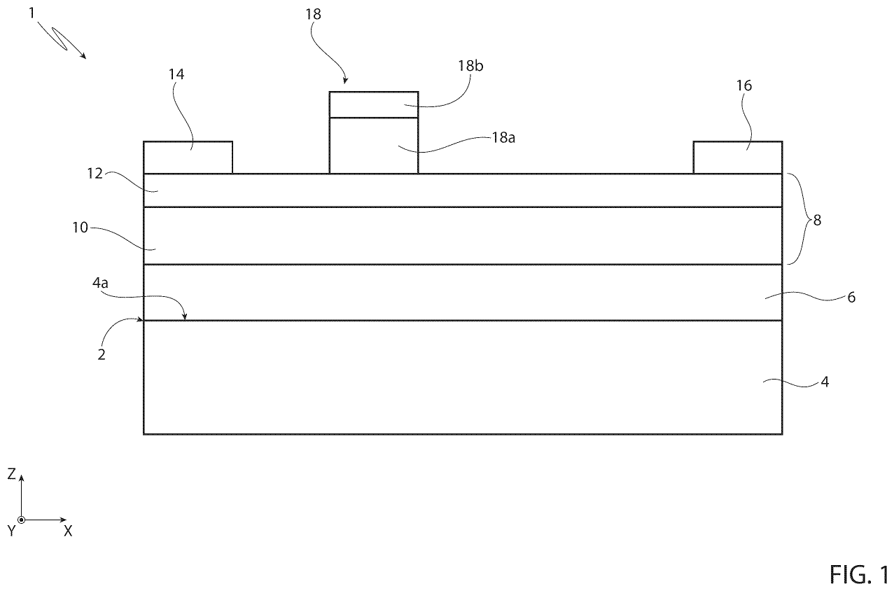

### DETAILED DESCRIPTION

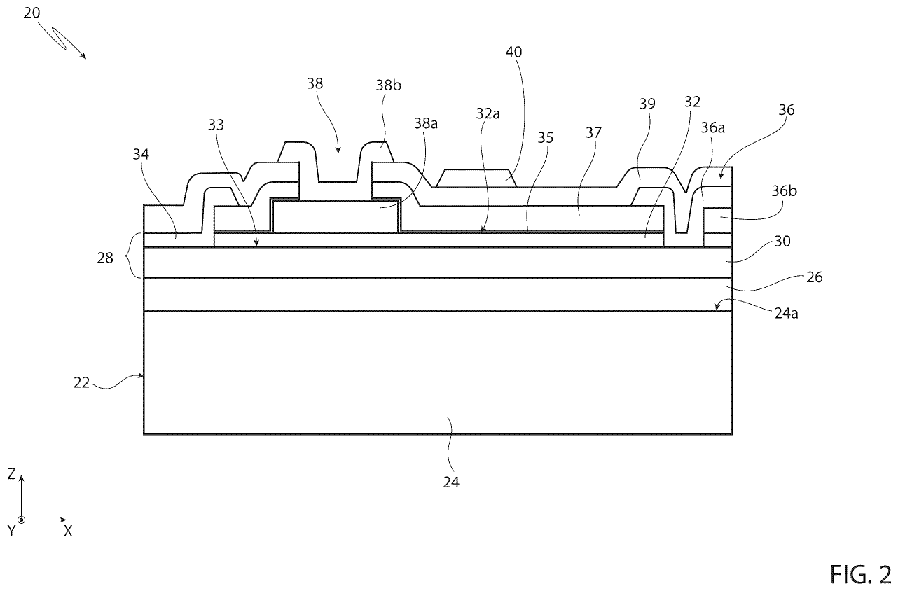

FIG. 2 schematically illustrates a portion of a HEMT device 20 according to an embodiment of the present disclosure, in a triaxial system of axes X, Y, Z orthogonal to each other, in a lateral sectional view on the XZ plane.

The HEMT device 20 comprises a semiconductor body 22, which in turn comprises a substrate 24, a buffer layer 26 extending on a face 24a of the substrate 24, and a heterostructure 28 extending on the buffer layer 26.

The substrate 24 is for example of silicon, or silicon carbide (SiC) or sapphire (Al₂O₃), or GaN. The substrate 24 may alternatively be of the SOI (“Silicon Over Insulator”) type.

The buffer layer 26 is of aluminum gallium nitride (AlGaN), or gallium nitride (GaN). N-type impurities are naturally present as a result of the manufacturing process of the buffer layer 26, therefore in one embodiment a P-type doping (e.g., carbon and/or iron doping) is introduced to compensate for the unwanted original N-type charges. In case the buffer layer 26 is of the intrinsic type from the start, no P-type doping is necessary.

The heterostructure 28 includes, in particular, a channel layer 30, extending over the buffer layer 26, and a barrier layer 32, extending over the channel layer 30, in direct physical contact with the channel layer 30. At an interface 33 between the channel layer 30 and the barrier layer 32, the conductive channel, in particular the two-dimensional electron gas (2DEG), is formed, in use.

The channel layer 30 is of intrinsic (undoped) gallium nitride (GaN); the barrier layer 32 is of undoped aluminum gallium nitride (AlGaN).

The buffer layer 26 has for example a thickness, along the Z-axis, comprised between 1 μm and 8 μm, for example 4 μm.

The channel layer 30 has for example a thickness, along the Z-axis, comprised between 100 nm and 700 nm, in particular of 500 nm and is of the undoped or intrinsic type.

The barrier layer 32 has for example a thickness, along the Z-axis, comprised between 10 nm and 30 nm for example 20 nm, and is of the undoped or intrinsic type.

The HEMT device 20 further comprises a gate electrode 38. The gate electrode 38 extends on the heterostructure 28 in electrical contact with an upper surface 32a of the barrier layer 32 without penetrating within the barrier layer 32. In particular, the gate electrode 38 comprises a doped gate region 38a and a conductive gate region 38b. The doped gate region 38a extends in direct physical and electrical contact with the upper surface 32a of the barrier layer 32. The conductive gate region 38b extends on the doped gate region 38a, in electrical contact with the doped gate region 38a. The structure formed by the conductive gate region 38b and the doped gate region 38a is known in the state of the art as “p-GaN gate.”

The doped gate region 38a is of P-type doped gallium nitride (GaN), with a dopant concentration comprised, for example, between 1·10¹⁸ at/cm³ and 1·10²⁰ at/cm³. The doped gate region 38a has a thickness along the Z-axis comprised, for example, between 50 nm and 150 nm, for example equal to 100 nm, and has an extension along the X-axis comprised, for example, between 1 μm and 3 μm, and has an extension along the Y-axis comprised, for example, between 100 μm and 1000 μm.

The conductive region 38b is of conductive material, such as tantalum (Ta), tantalum nitride (TaN), titanium (Ti), titanium nitride (TiN), palladium (Pa), tungsten (W), tungsten silicide (WSi₂), titanium aluminum (Ti/Al) or nickel gold (Ni/Au). In one embodiment, the conductive gate region 38b is a Ti/AlCu/TiN stack.

As is known, the doped gate region 38a modifies the band diagram of the heterostructure 28 in such a way that, in the absence of a voltage applied to the doped gate region 38a, the 2DEG is depleted in the area below the doped gate region 38a. Consequently, in the absence of such a gate voltage, the conductive channel is not present.

An insulating layer 35 extends continuously, laterally to the conductive region 38b, on the doped gate region 38a and the upper surface 32a of the barrier layer 32, in direct physical contact with the doped gate region 38a and with the barrier layer 32.

The insulating layer 35 is for example of aluminum oxide (Al₂O₃) and has for example a thickness along the Z-axis comprised between 3 nm and 10 nm.

A first passivating layer 37 (e.g., of SiN or SiO₂) extends on the insulating layer 35, in physical contact with the insulating layer 35.

The HEMT device 20 further comprises a source electrode 34. The source electrode 34 extends at a distance along the X-axis with respect to a first side of the gate electrode 38 and at least in part on the heterostructure 28. In one embodiment, the source electrode 34 extends in depth in the heterostructure 28, ending in direct electrical contact with the channel layer 30 (and with the 2DEG, when present during use). In another embodiment, the source electrode 34 extends in depth in the heterostructure 28 without reaching the channel layer 30, ending within the barrier layer 32. In a further embodiment, the source electrode 34 extends on the upper surface 32a of the barrier layer 32, in electrical contact with the barrier layer 32. The depth of the recession of the source electrode 34 with respect to the barrier layer 32 or the channel layer 30 affects the contact resistance of the device.

The HEMT device 20 further comprises a drain electrode 36, extending at least in part on the heterostructure 28, laterally at a distance along the X-axis from the gate electrode 38.

In one embodiment, a distance along the X-axis between the source electrode 34 and the gate electrode 38 is shorter than a distance along the X-axis between the drain electrode 36 and the gate electrode 38. In another embodiment, the distance along the X-axis between the source electrode 34 and the gate electrode 38 is equal to the distance along the X-axis between the drain electrode 36 and the gate electrode 38.

According to one embodiment of the present disclosure, the drain electrode 36 comprises a conductive drain region 36a and a doped drain region 36b. The conductive drain region 36a extends at least in part on the heterostructure 28, laterally at a distance with respect to a second side opposite to the first side of the gate electrode 38 along the X-axis. In one embodiment, the conductive drain region 36a extends in depth in the heterostructure 28, ending in direct electrical contact with the channel layer 30 (and with the 2DEG, when present during use). In another embodiment, the conductive drain region 36a extends in depth in the heterostructure 28 without reaching the channel layer 30, ending within the barrier layer 32. In a further embodiment, the conductive drain region 36a extends on the upper surface 32a of the barrier layer 32, in electrical contact with the barrier layer 32.

The doped drain region 36b extends on the upper surface 32a of the barrier layer 32, laterally along the X-axis with respect to the conductive drain region 36a, in direct electrical contact with the conductive drain region 36a and with the upper surface 32a of the barrier layer 32. In particular, a distance along the X-axis between the conductive drain region 36a and the gate electrode 38 is shorter than a distance along the X-axis between the doped drain region 36b and the gate electrode 38. In other words, the conductive drain region 36a is interposed, along the X-axis, between the gate electrode 38 and the doped drain region 36b.

The source electrode 34 and the conductive drain region 36a are of one or more materials that allow an ohmic contact with the channel layer 30. In particular, the source electrode 34 and the conductive drain region 36a are of metal material with a reduced work function value (e.g., comprised between 3.5 and 4.5 eV).

In one embodiment, the source electrode 34 and the conductive drain region 36a include titanium (Ti) or tantalum (Ta). In a further embodiment, the source electrode 34 and the conductive drain region 36a comprise two or more stacked layers of conductive materials, such as for example Ti (or Ta), AlCu, TiN (or TaN). In one embodiment, the source electrode 34 and the conductive drain region 36a are a Ti/AlCu/TiN stack. As an alternative to titanium, tantalum (e.g., Ta/AlCu/TaN or Ta/AlCu/Ta) may be used. When the source electrode 34 and the conductive drain region 36a comprise the aforementioned plurality of stacked layers, the titanium (or tantalum) is in direct contact with the channel layer 30.

Using a stack for the source electrode 34 and the doped drain region 36a allows the resistivity of the source electrode 34 to be reduced and the thermal dissipation to be improved.

The doped drain region 36b is of P-type doped gallium nitride (GaN), with a dopant concentration comprised, for example, between 1·10¹⁸ at/cm³ and 1·10²⁰ at/cm³. The doped drain region 36b has a thickness along the Z-axis comprised, for example, between 50 nm and 200 nm, for example equal to 100 nm, and has an extension along the X-axis comprised, for example, between 0.5μm and 3μm, and has an extension along the Y-axis comprised, for example, between 100 μm and 1000 μm. In particular, the doped drain region 36b is of the same material as the doped gate region 38a.

The doped drain region 36b is adapted, in use, to inject holes in the buffer layer 26 through the heterostructure 28, thereby compensating for electrons trapped in trap states within the buffer layer 26, and preventing degradation of the R_{ON} of the HEMT device 20.

It should be noted that, similarly to what has been described for the doped gate region 38a, the doped drain region 36b modifies the band diagram of the heterostructure 28 in such a way that, in the absence of a voltage applied to the doped drain region 36b, the 2DEG is depleted in the area below the doped drain region 36b. Consequently, in the absence of such a drain voltage, a conductive channel is not present in the area below the doped drain region 36b. Since the conductive drain region 36a is interposed between the gate electrode 38 and the doped drain region 36b, the conductive channel is always present between the gate electrode 38 and the conductive drain region 36a. If the doped drain region 36b were instead interposed between the gate electrode 38 and the conductive drain region 36a, the absence of the conductive channel between the gate electrode 38 and the conductive drain region 36a would degrade the R_{ON} of the HEMT device 20. To avoid unwanted depletion of the 2DEG, it would therefore be necessary to increase the thickness of the barrier layer 32 and modify the structure of the gate electrode 38, with significant disadvantages in terms of complexity and cost of the manufacturing process of the HEMT device. Therefore, the configuration envisaged by the present disclosure allows to compensate for trap states in the buffer layer 26 by injecting holes from the doped drain region 36b to the buffer layer 26, without interrupting the conductive channel between the gate electrode 38 and the conductive drain region 36a, and without requiring additional complications in the manufacturing process of the HEMT device 20.

In one embodiment, the HEMT device 20 further includes a second passivating layer 39 (e.g., of SiN or SiO₂) that extends above the source electrode 34 and the drain electrode 36, for protecting and electrically insulating the same, and over the first passivating layer 37. Electrical contact regions are formed through the passivating layer 39 for biasing the source electrode 34 and the drain electrode 36, in a manner known per se.

Optionally, the HEMT device 20 further includes a field plate 40 extending on the second passivating layer 39, laterally interposed along the X-axis between, and at a distance from, the gate electrode 38 and the drain electrode 36. The field plate 40 is adapted to be biased, during use, to a voltage equal to the voltage applied to the source electrode 34.

The field plate 40 is of a conductive material, such as for example tantalum (Ta), tantalum nitride (TaN), titanium nitride (TiN), palladium (Pa), tungsten (W), tungsten silicide (WSi₂), titanium aluminum (Ti/Al) or nickel gold (Ni/Au).

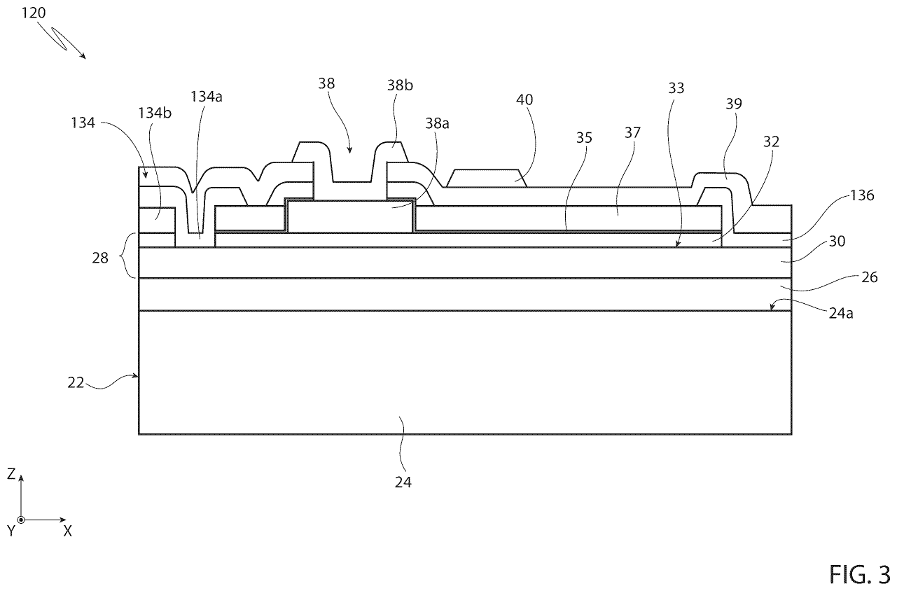

FIG. 3 schematically illustrates a portion of a HEMT device 120 according to another embodiment of the present disclosure, in a triaxial system of axes X, Y, Z orthogonal to each other, in a lateral sectional view on the XZ plane. In FIG. 3, elements of the HEMT device 120 that are in common with the HEMT device 20 of FIG. 2 are indicated by the same reference numerals and are not further described.

The HEMT device 120 includes a drain electrode 136, extending at a distance along the X-axis with respect to a first side of the gate electrode 38 and at least in part on the heterostructure 28. In one embodiment, the drain electrode 136 extends in depth in the heterostructure 28, ending in direct electrical contact with the channel layer 30 (and with the 2DEG, when present during use). In another embodiment, the drain electrode 136 extends in depth in the heterostructure 28 without reaching the channel layer 30, ending within the barrier layer 32. In a further embodiment, the drain electrode 136 extends on the upper surface 32a of the barrier layer 32, in electrical contact with the barrier layer 32.

The HEMT device 120 further includes a source electrode 134, extending at least in part on the heterostructure 28, laterally at a distance along the X-axis from the gate electrode 38.

In one embodiment, a distance along the X-axis between the source electrode 134 and the gate electrode 38 is shorter than a distance along the X-axis between the drain electrode 136 and the gate electrode 38. In another embodiment, the distance along the X-axis between the source electrode 134 and the gate electrode 38 is equal to the distance along the X-axis between the drain electrode 136 and the gate electrode 38.

According to one embodiment of the present disclosure, the source electrode 134 comprises a conductive source region 134a and a doped source region 134b. The conductive source region 134a extends at least in part on the heterostructure 28, laterally at a distance with respect to a second side opposite to the first side of the gate electrode 38 along the X-axis. In one embodiment, the conductive source region 134a extends in depth in the heterostructure 28, ending in direct electrical contact with the channel layer 30 (and with the 2DEG, when present during use). In another embodiment, the conductive source region 134a extends in depth in the heterostructure 28 without reaching the channel layer 30, ending within the barrier layer 32. In a further embodiment, the conductive source region 134a extends on the upper surface 32a of the barrier layer 32, in electrical contact with the barrier layer 32.

The doped source region 134b extends on the upper surface 32a of the barrier layer 32, laterally along the X-axis with respect to the conductive source region 134a, in direct electrical contact with the conductive source region 134a and the upper surface 32a of the barrier layer 32. In particular, a distance along the X-axis between the conductive source region 134a and the gate electrode 38 is shorter than a distance along the X-axis between the doped source region 134b and the gate electrode 38. In other words, the conductive source region 134a is interposed, along the X-axis, between the gate electrode 38 and the doped source region 134b.

The drain electrode 136 and the conductive source region 134a are of one or more materials that allow an ohmic contact with the channel layer 30. In particular, the drain electrode 136 and the conductive source region 134a are of metal material with a reduced work function value (e.g., comprised between 3.5 and 4.5 eV).

In one embodiment, the drain electrode 136 and the conductive source region 134a include titanium (Ti) or tantalum (Ta). In a further embodiment, the drain electrode 136 and the conductive source region 134a comprise two or more stacked layers of conductive materials, such as for example Ti (or Ta), AlCu, TiN (or TaN). In one embodiment, the drain electrode 136 and the conductive source region 134a are a Ti/AlCu/TiN stack. As an alternative to titanium, tantalum (e.g., Ta/AlCu/TaN or Ta/AlCu/Ta) may be used. When the drain electrode 136 and the conductive source region 134a comprise the aforementioned plurality of stacked layers, the titanium (or tantalum) is in direct contact with the channel layer 30.

Using a stack for the source electrode 134 and the doped drain region 136 allows the resistivity of the source electrode 134 to be reduced and the thermal dissipation to be improved.

The doped source region 134b is of P-type doped gallium nitride (GaN), with a dopant concentration comprised, for example, between 1·10¹⁸ at/cm³ and 1·10²⁰ at/cm³. The doped source region 134 b has a thickness along the Z-axis comprised, for example, between 50 nm and 200 nm, for example, equal to 100 nm, and has an extension along the X-axis comprised, for example, between 0.5 μm and 3 μm, and has an extension along the Y-axis comprised, for example, between 100 μm and 1000 μm. In particular, the doped source region 134 b is of the same material as the doped gate region 38a.

The doped source region 134b is adapted to operate similarly to what has been previously described with reference to the doped drain region 36b of the HEMT device 20 of FIG. 2.

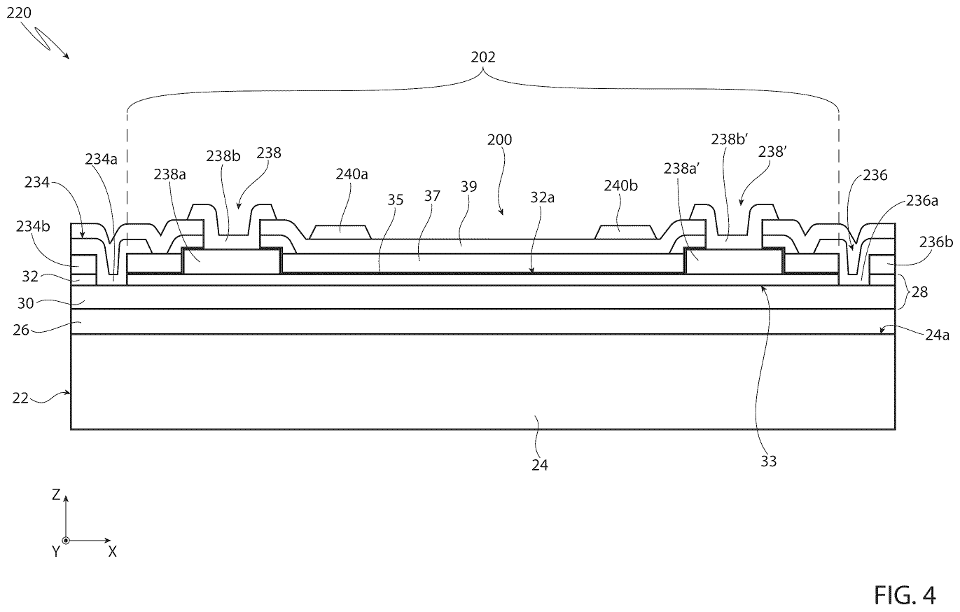

FIG. 4 schematically illustrates a portion of a HEMT device 220 according to a further embodiment of the present disclosure, in a triaxial system of axes X, Y, Z orthogonal to each other, in a lateral sectional view on the XZ plane. In FIG. 4, elements of the HEMT device 220 that are in common with the HEMT device 20 of FIG. 2 and with the HEMT device 120 of FIG. 3 are indicated by the same reference numerals and are not further described.

In particular, the HEMT device 220 is a bidirectional HEMT device, and includes a first gate electrode 238 and a second gate electrode 238′, extending on the heterostructure 28, in electrical contact with the upper surface 32a of the barrier layer 32, and at a distance from each other along the X-axis. In particular, the first gate electrode 238 and the second gate electrode 238′ delimit, along the X-axis, a central portion 200 of the HEMT device 220.

The first and the second gate electrodes 238, 238′ include respective doped gate regions 238a, 238a′ and respective conductive gate regions 238b, 238b′.

The doped gate regions 238a, 238a′ and the conductive gate regions 238b, 238b′ are of the same type as, respectively, the doped gate region 38a and the conductive gate region 38b of the HEMT device 20 described with reference to FIG. 2.

The HEMT device 220 further includes a first source electrode 234 and a second source electrode 236. The first source electrode 234 extends at least in part on the heterostructure 28, laterally at a distance with respect to the first gate electrode 238 along the X-axis and externally with respect to a first side of the central portion 200 of the HEMT device 220. The second source electrode 236 extends at least in part on the heterostructure 28, laterally at a distance with respect to the second gate electrode 238′ and externally with respect to a second side, opposite to the first along the X-axis, of the central portion 200 of the HEMT device 220.

The first and the second source electrodes 234, 236 include a first and a second conductive source region 234a, 236a, respectively and a first and a second doped source region 234b, 236b, respectively.

The first conductive source region 234a and the second conductive source region 236a face, along the X-axis, the first gate electrode 238 and the second gate electrode 238′, respectively, externally with respect to opposite sides along the X-axis of the central portion 200 of the HEMT device 220. In greater detail, the first conductive source region 234a and the second conductive source region 236a delimit, along the X-axis, a channel region 202 of the HEMT device 220. The channel region 202 includes therewithin the central portion 200 and the first and the second gate electrodes 238, 238′.

The first doped source region 234b and the second doped source region 236b extend laterally to the first conductive source region 234a and the second conductive source region 236a, respectively, externally to the channel region 202 from a first and a second side opposite to the first along the X-axis of the channel region 202, respectively.

The first conductive source region 234a and the second conductive source region 236a are of the same type as the conductive source region 134a of the HEMT device 120 of FIG. 3.

The first doped source region 234b and the second doped source region 236b are of the same type as the doped source region 134b of the HEMT device 120 of FIG. 3, and are adapted to operate similarly to what has been previously described with reference to the doped drain region 36b of the HEMT device 20 of FIG. 2.

Optionally, the HEMT device 220 further includes a first field plate 240a and a second field plate 240b, extending in the central portion 200 on the second passivating layer 39, along the X-axis laterally at a distance from each other and at a distance from the first and the second gate electrodes 238, 238′. In particular, a distance along the X-axis between the first field plate 240a and the first gate electrode 238 is shorter with respect to a distance along the X-axis between the first field plate 240a and the second gate electrode 238′. Similarly, a distance along the X-axis between the second field plate 240b and the second gate electrode 238′ is shorter with respect to a distance along the X-axis between the second field plate 240b and the first gate electrode 238.

The first field plate 240a and the second field plate 240b are adapted, in use, to be coupled at a voltage equal to the biasing voltage of the second source electrode 236 and the first source electrode 234, respectively.

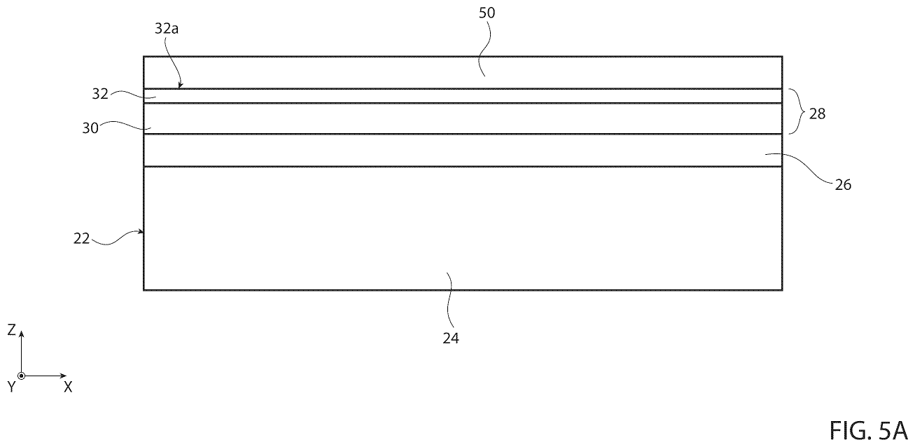

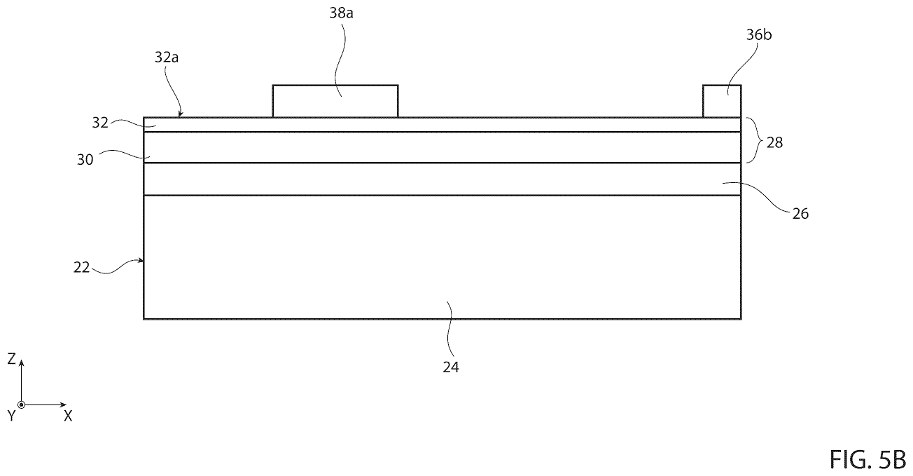

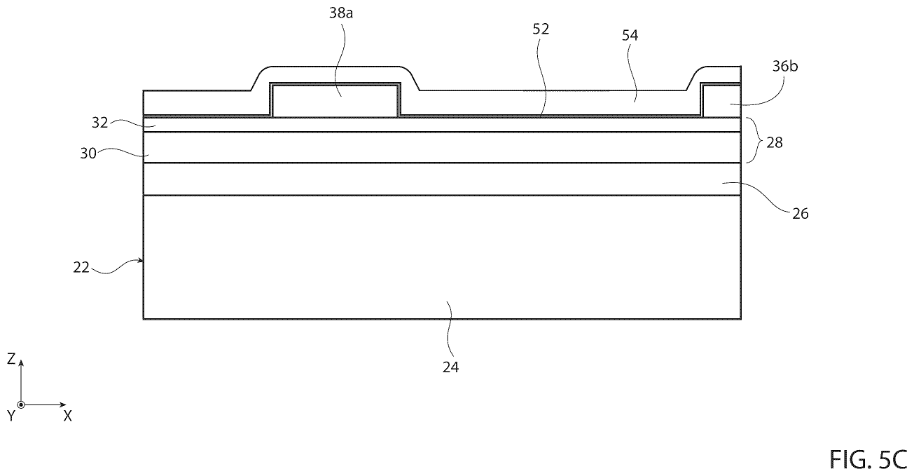

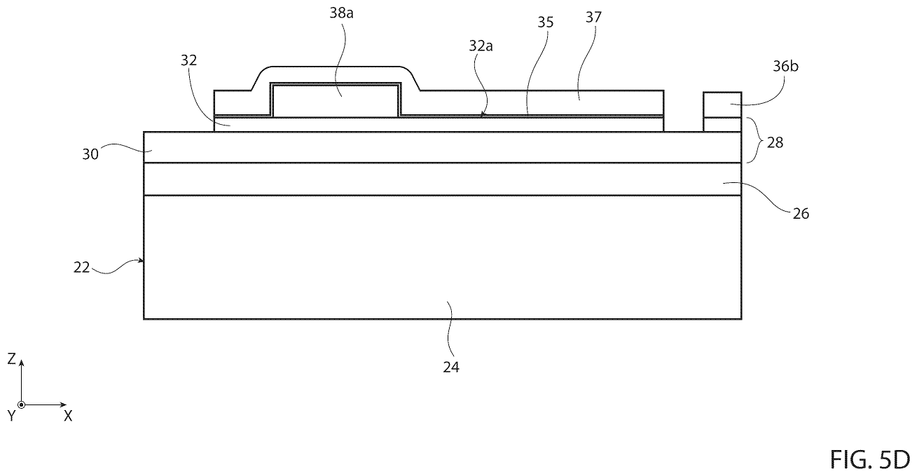

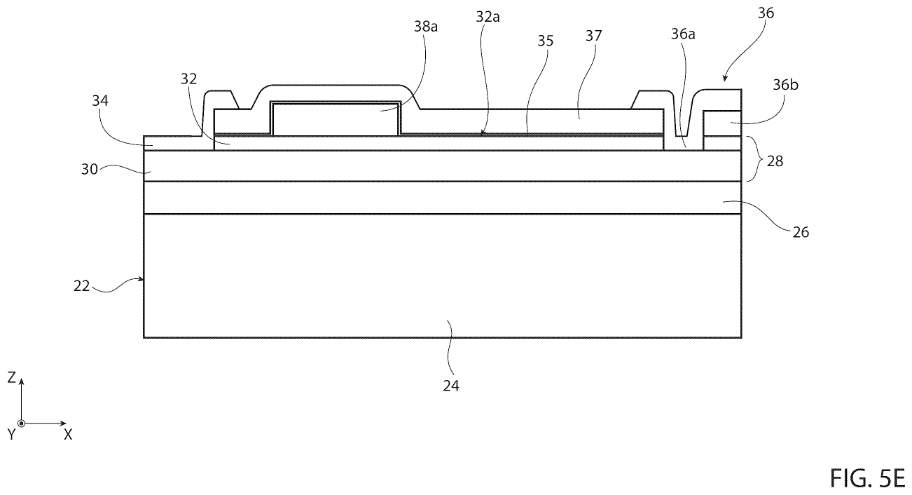

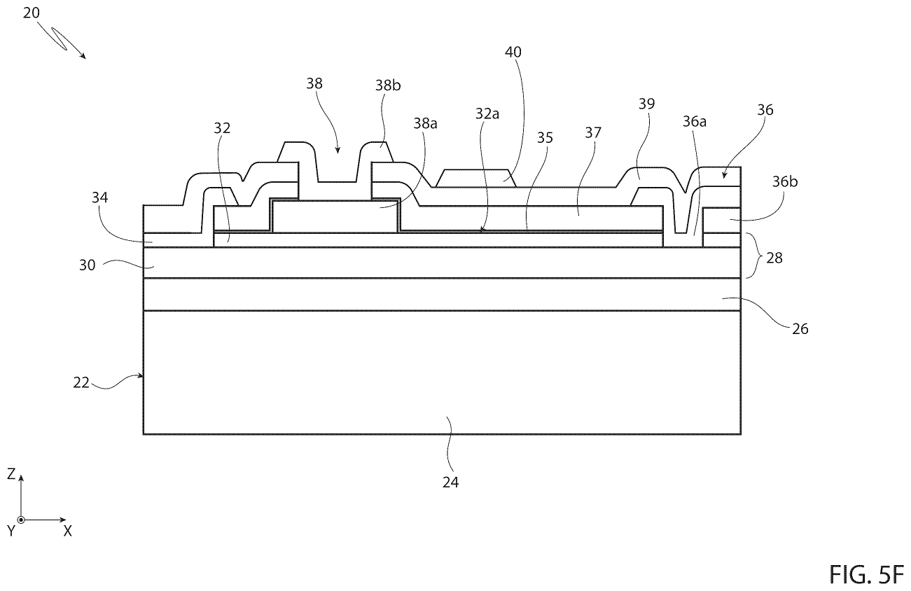

With reference to FIGS. 5A-5F, manufacturing steps of the portion of the HEMT device 20 illustrated in FIG. 2 are now described, limitedly to the formation of elements relevant to the present disclosure and according to one embodiment. FIGS. 5A-5E are lateral sectional views on the XZ plane.

With reference to FIG. 5A, after having formed the semiconductor body 22 in a manner known per se (e.g., by one or more epitaxial growths on the substrate 24, with appropriate doping), a deposition step is performed (e.g., through metal-organic vapor-phase epitaxy “MOCVD”) of a doped semiconductive layer 50 on the barrier layer 32, in direct physical contact with the upper surface 32a of the barrier layer 32. The doped semiconductive layer 50 is of P-type doped gallium nitride (“p-GaN”), with a dopant concentration comprised, for example, between 1·10¹⁸ at/cm³ and 1·10²⁰ at/cm³. The doped semiconductive layer 50 has a thickness along the Z-axis comprised, for example, between 50 nm and 200 nm, for example equal to 100 nm.

With reference to FIG. 5B, one or more masked etch steps are performed (e.g., by photolithography and etch steps, known per se) to remove selective portions of the doped semiconductive layer 50, thus patterning the doped gate region 38a and the doped drain region 36b, placed at a distance along the X-axis from a first side of the doped gate region 38a.

With reference to FIG. 5C, a deposition step of an insulating material layer 52 is performed. In particular, a deposition step of aluminum oxide (Al₂O₃) is performed through Atomic Layer Deposition (ALD). The insulating material layer 52 extends continuously on, and in direct physical contact with, the doped gate region 38a, the doped drain region 36b, and the upper surface 32a of the barrier layer 32 laterally to the doped gate region 38a and the doped drain region 36b.

A deposition step of a first passivating material layer 54 is then performed. For example, a Plasma-Enhanced Chemical Vapor Deposition (PECVD) step of silicon oxide (SiO₂) or silicon nitride (SiN) is performed. The first passivating material layer 54 extends on the insulating material layer 52, in direct physical contact with the insulating material layer 52.

With reference to FIGS. 5D and 5E, the formation steps of the source electrode 34 and the drain electrode 36 are now described.

With reference to FIG. 5D, one or more masked etch steps are performed to remove selective portions of the first passivating material layer 54 and the insulating material layer 52. The insulating layer 35 and the first passivating layer 37 are thus patterned. Furthermore, there are thus exposed the doped drain region 36b, portions of the barrier layer 32 laterally adjacent to the doped drain region 36b, and a portion of the barrier layer 32 placed at a distance from a second side, opposite to the first along the X-axis, of the doped gate region 38a.

In one embodiment, as illustrated in FIG. 5D, a selective etch step is then performed to remove exposed portions of the barrier layer 32, exposing respective portions of the channel layer 30.

In an alternative embodiment (not illustrated), the selective etch step is performed to remove exposed portions of the barrier layer 32, without reaching and exposing respective portions of the channel layer 30 (i.e., the etching ends within the barrier layer 32).

In a further alternative embodiment (not illustrated), the selective etching to remove exposed portions of the barrier layer 32 is omitted.

With reference to FIG. 5E, one or more deposition steps of metal material are then performed, in particular on the exposed regions of the barrier layer 32 (or of the channel layer 30 in the embodiment wherein portions of the channel layer 30 are exposed) and on the doped drain region 36b. For example, successive deposition steps are performed through evaporation or sputtering of titanium (Ti), aluminum-copper (AlCu) and titanium nitride (TiN), to obtain a Ti/AlCu/TiN stack.

A patterning step is then performed (e.g., through successive photolithography and etch steps, or through lift-off) to define the source electrode 34 and the conductive region 36a of the drain electrode 36.

With reference to FIG. 5F, the formation steps of the gate electrode 38 are described.

A deposition step of the second passivating layer 39 is performed. For example, a Plasma Enhanced Chemical Vapor Deposition (PECVD) step of silicon oxide (SiO₂) or silicon nitride (SiN) is performed. The second passivating layer 39 extends on the source contact 34, the drain contact 36 and the first passivating layer 37.

Successively, a masked etch step is performed to remove selective portions of the second passivating layer 39, the first passivating layer 37 and the insulating layer 35 at the doped gate region 38a, thus exposing at least in part an upper surface of the doped gate region 38a.

Subsequently, one or more metal material deposition steps are performed, in particular on the upper surface of the doped gate region 38a and on the second passivating layer 39. For example, successive deposition steps are performed through evaporation or sputtering of titanium (Ti), aluminum-copper (AlCu) and titanium nitride (TiN), to obtain a Ti/AlCu/TiN stack.

A patterning step is then performed (e.g., through successive photolithography and etch steps, or through lift-off), defining the conductive gate region 38b and, in one embodiment, the field plate 40.

Optionally, a deposition step of passivating or insulating material (e.g., SiO₂ or SiN) is also performed above the conductive gate region 38b, the field plate 40 and the second passivating layer 39, for protecting and electrically insulating the same. Electrical contact regions are formed through the passivating layers for biasing the source electrode 34, the drain electrode 36 and the gate electrode 38, in a manner known per se.

The HEMT device 20 of FIG. 2 is thus obtained.

Finally, it is clear that modifications and variations may be made to what has been described and illustrated here without thereby departing from the scope of the present disclosure.

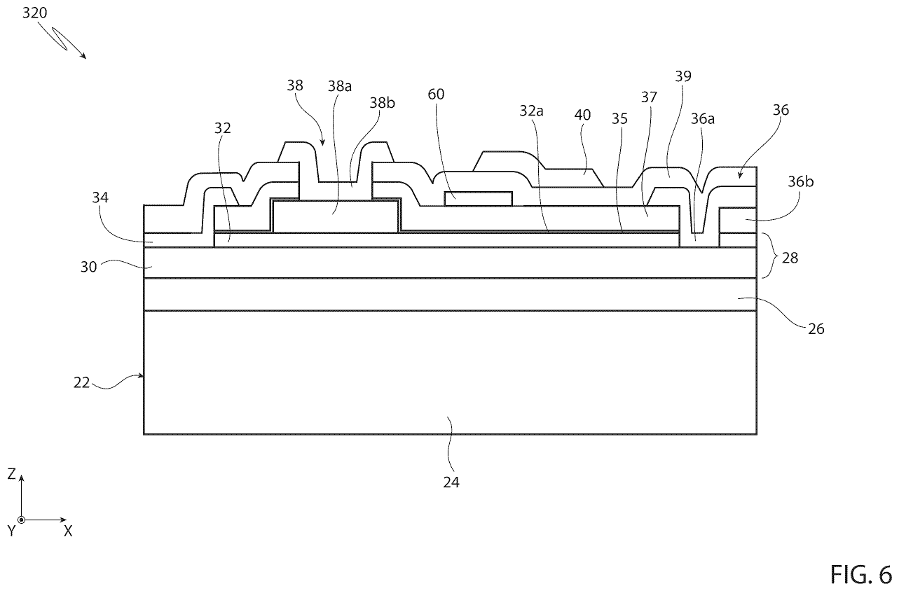

For example, as illustrated in FIG. 6 and according to an embodiment of the present disclosure, during the patterning step of the source electrode 34 and the conductive drain region 36a, an additional field plate 60 is patterned. The field plate 60 extends laterally interposed between, and at a distance from, the gate electrode 38 and the drain electrode 36, and interposed along the Z-axis between the first passivating layer 37 and the second passivating layer 39. The HEMT device 320 of FIG. 6 is thus obtained.

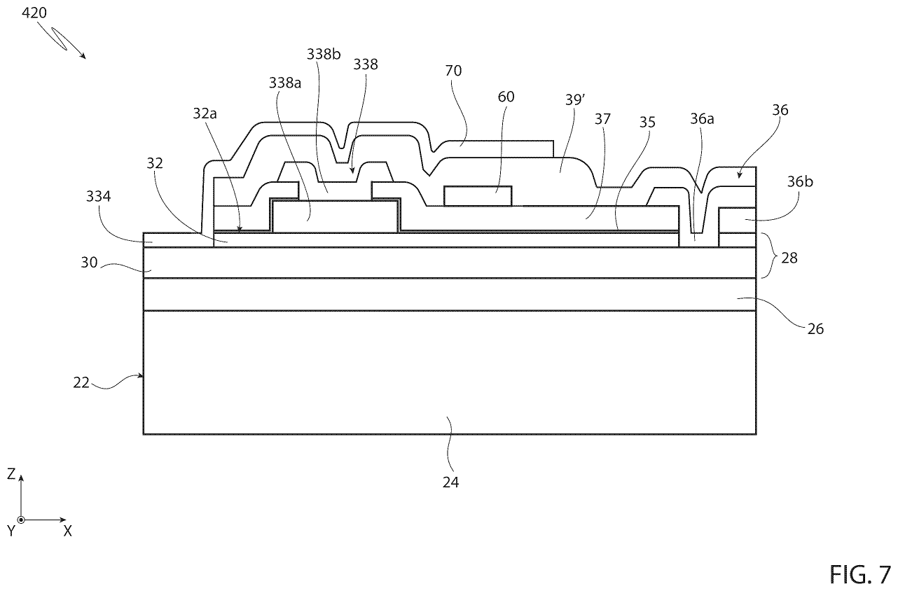

According to a further embodiment illustrated in FIG. 7, the definition of a gate electrode 338 is performed concurrently with the definition of the drain electrode 36 and the field plate 60 and is followed by the concurrent definition of a source electrode 334 and a field plate 70.

In detail, starting from the semi-finished product of FIG. 5C and with reference to FIG. 7, a masked etch step is performed to remove selective portions of the first passivating material layer 54, the insulating material layer 52 and the barrier layer 32, thus exposing the doped drain region 36b, portions of the channel layer 30 laterally adjacent to the doped drain region 36b, and an upper surface of the doped gate region 38a.

A conductive gate region 338b of the gate electrode 338, the conductive drain region 36a and the field plate 60 are then formed, for example through successive steps of metal material deposition and patterning through photolithography and etching.

A deposition step of a second passivating material layer 39′ is then performed on the conductive gate region 338b, on the field plate 60, on the conductive drain region 36a and on the first passivating material layer 54.

Subsequently, a masked etching is performed to remove selective portions of the second passivating material layer 39′, first passivating material layer 54, of the insulating material layer 52 and the barrier layer 32, thus exposing a portion of the channel layer 30 placed laterally to the doped gate region 338a. In detail, the exposed portion of the channel layer 30 extends facing one side of the doped gate region 338a opposite, along the X-axis, to the side of the doped gate region 338a that the doped drain region 336b faces. The insulating layer 35 and the first passivating layer 37 are thus patterned.

Finally, there are concurrently formed the source electrode 334 on the exposed portion of the channel layer 30, in electrical contact with the channel layer 30, and the field plate 70 on the second insulating material layer 39′. The source electrode 334 and the field plate 70 are formed in a single piece, for example through successive steps of metal material deposition and patterning.

The HEMT device 420 of FIG. 7 is thus obtained.

From what has been previously exposed, the advantages that the present disclosure affords are evident.

In particular, an improvement in dynamic performance is observed due to a reduction in the on-state drain-to-source resistance (R_{ON}).

For instance, with reference to the HEMT device 20 of FIG. 2, the presence of a doped drain region 36b placed outside of a conductive channel region delimited by the source electrode 34 and the conductive drain region 36a, allows the injection of holes in the buffer layer 26 compensating for the negative charges present, without interrupting the conductive channel between the source and drain ohmic contacts. Furthermore, the present disclosure allows the doped gate region 38a and the doped drain region 36b to be formed concurrently, without introducing additional complications to the manufacturing process. It should be noted that the advantages described herein with reference to the HEMT device 20 of FIG. 2 similarly apply to the HEMT devices 120 of FIGS. 3, 220 of FIGS. 4, 320 of FIG. 6, and 420 of FIG. 7.

A HEMT device (20; 120; 220; 320; 420) is summarized as including: a semiconductor body (22) including a substrate (24), a buffer layer (26) having N-type electrical conductivity on the substrate (24), and a heterostructure (28) on the buffer layer (26), wherein the heterostructure (28) includes a channel layer (30), configured to accommodate, in use, a conductive channel of the HEMT device, and a barrier layer (32) on the channel layer (30); a first control terminal (38; 238) extending completely above the barrier layer (32) and in electrical contact with a surface (32a) of the barrier layer (32); a first conduction terminal (36; 134; 234) extending at least in part on the barrier layer (32); a second conduction terminal (34; 136; 236; 334) extending at least in part on the barrier layer (32); characterized in that the first conduction terminal (36; 134; 234)includes: a first conductive region (36 a; 134 a; 234 a) extending in electrical contact with the channel layer (30) and forming an ohmic contact with the channel layer (30); a second conductive region (36b; 134b; 234b), of semiconductor material having P-type electrical conductivity, extending completely above the barrier layer (32) and in electrical contact with the surface (32a) of the barrier layer (32) and with the first conductive region (36a; 134a; 234a); wherein the first conductive region (36a; 134a; 234a) is interposed between the first control terminal (38; 238; 338) and the second conductive region (36b; 134b; 234b).

The first control terminal (38; 238; 338) includes: a first control region (38a; 238a), of semiconductor material having P-type conductivity, extending on the surface (32a) of the barrier layer (32), in electrical contact with the barrier layer (32); a second control region (38b; 238b; 338b), of metal material, extending on the first control region (38a; 238a) in direct electrical contact with the first control region (38a; 238a).

The first control region (38a; 238a) is of a same material as the second conductive region (36b; 134b; 234b), in particular GaN.

The HEMT device (220) further includes: a second control terminal (238′) extending completely above the barrier layer (32) and in electrical contact with the surface (32a) of the barrier layer (32); wherein: the first control terminal (238) is interposed between the first conduction terminal (234) and the second control terminal (238′), the second control terminal (238′) is interposed between the first control terminal (238) and the second conduction terminal (236), and the second conduction terminal (236) includes: a third conductive region (236a) in electrical contact with the channel layer (30) and forming an ohmic contact with the channel layer (30); a fourth conductive region (236b) of semiconductor material having P-type electrical conductivity, extending completely above the barrier layer (32) and in electrical contact with the surface (32a) of the barrier layer (32) and with the third conductive region (236a); wherein the third conductive region (236a) is interposed between the second control terminal (238′) and the fourth conductive region (236b).

The fourth conductive region (236b) is of the same material as the second conductive region (234b), in particular GaN.

The second control terminal (238′) includes: a third control region (238a′), of semiconductor material having P-type conductivity, extending on the surface (32a) of the barrier layer (32), in electrical contact with the barrier layer (32); a fourth control region (238b′), of metal material, extending on the third control region (238a′) in direct electrical contact with the second control region (238a′).

The third control region (238a′) is of the same material as the second conductive region (36b; 134b; 234b), in particular GaN.

The first conductive region (36a; 134a; 234a) and the second conduction terminal (34; 136; 236; 334) extend through part of the heterostructure (28), in direct physical and electrical contact with the channel layer (30).

The first conductive region (36a; 134a; 234a) and the second conduction terminal (34; 136; 236; 334) extend through part of the heterostructure (28), ending within the barrier layer (32).

The first conductive region (36a; 134a; 234a) and the second conduction terminal (34; 136; 236; 334) extend on the surface (32a) of the barrier layer (32), in direct physical and electrical contact with the surface (32a) of the barrier layer (32).

A method of manufacturing a HEMT device (20; 120; 220; 320; 420) is summarized as including the steps of: forming a buffer layer (26) having N-type electrical conductivity on a substrate (24); forming a heterostructure (28) on the buffer layer (26), including forming, on the buffer layer (26), a channel layer (30) configured to accommodate, in use, a conductive channel of the HEMT device, and forming a barrier layer (32) on the channel layer (30); forming a first control terminal (38; 238) completely above the barrier layer (32) and in electrical contact with a surface (32a) of the barrier layer (32); forming a first conduction terminal (36; 134; 234) at least in part on the barrier layer (32); forming a second conduction terminal (34; 136; 236; 334) at least in part on the barrier layer (32), characterized in that the step of forming the first conduction terminal (36; 134; 234) includes the steps of: forming a first conductive region (36a; 134a; 234a) in electrical contact with the channel layer (30) and forming an ohmic contact with the channel layer (30); forming a second conductive region (36b; 134b; 234b), of semiconductor material having P-type electrical conductivity, completely above the barrier layer (32) and in electrical contact with the surface (32a) of the barrier layer (32) and with the first conductive contact region (36a; 134a; 234a); wherein forming the first conductive region (36a; 134a; 234a) includes forming the first conductive region (36a; 134a; 234a) between the first control terminal (38; 238; 338) and the second conductive region (36b; 134b; 234b).

The step of forming the first control terminal (38; 238; 338) includes: forming a first control region (38a; 238a), of semiconductor material having P-type conductivity, on the surface (32a) of the barrier layer (32) and in electrical contact with the barrier layer (32); forming a second control region (38b; 238b; 338b), of metal material, on the first control region (38a; 238a) and in direct electrical contact with the first control region (38a; 238a).

The step of forming the first control region (38a; 238a) is performed concurrently with the step of forming the second conductive region (36b; 134b; 234b), and wherein the first control region (38a; 238a) is of a same material as the second conductive region (36b; 134b; 234b), in particular GaN.

The manufacturing method of a HEMT device (220) further includes the steps of:
forming a second control terminal (238′) completely above the barrier layer (32) and in electrical contact with the surface (32a) of the barrier layer (32), wherein: the first control terminal (238) is formed between the first conduction terminal (234) and the second control terminal (238′), the second control terminal (238′) is formed between the first control terminal (238) and the second conduction terminal (236), and forming the second conduction terminal (236) includes: forming a third conductive region (236a) in electrical contact with the channel layer (30) and defining an ohmic contact with the channel layer (30); forming a fourth conductive region (236b), of semiconductor material having P-type electrical conductivity, completely above the barrier layer (32) and in electrical contact with the surface (32a) of the barrier layer (32) and with the third conductive region (236a); wherein the third conductive region (236a) is formed between the second control terminal (238′) and the fourth conductive region (236b).

The step of forming the second control terminal (238′) includes: forming a third control region (238a′), of semiconductor material having P-type conductivity, on the surface (32a) of the barrier layer (32), in electrical contact with the barrier layer (32); and forming a fourth control region (238b′), of metal material, on the third control region (238a′) in direct electrical contact with the second control region (238a′), wherein the steps of forming the third conductive region (236b) and the third control region (238a′) are performed concurrently with the step of forming the second conductive region (36b; 134b; 234b), and wherein the fourth conductive region (236b) and the third control region (238a′) are of the same material as the second conductive region (36b; 134b; 234b), in particular GaN.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A HEMT device comprising:
a semiconductor body including a substrate, a buffer layer having N-type electrical conductivity on the substrate, and a heterostructure on the buffer layer, wherein the heterostructure includes a channel layer, configured to accommodate, in use, a conductive channel of the HEMT device, and a barrier layer on the channel layer;
a first control terminal extending completely above the barrier layer and coupled to a surface of the barrier layer;
a first conduction terminal extending at least in part on the barrier layer; and
a second conduction terminal extending at least in part on the barrier layer;
wherein the first conduction terminal includes:
a first, u-shaped conductive region extending coupled to the channel layer and forming an ohmic contact with the channel layer; and
a second conductive region, of a semiconductor material having P-type electrical conductivity, extending completely above the barrier layer and coupled to the surface of the barrier layer and with the first conductive region;
wherein the first conductive region is interposed between the first control terminal and the second conductive region.

2. The HEMT device according to claim 1, wherein the first control terminal includes:
a first control region, of the semiconductor material having P-type conductivity, extending on the surface of the barrier layer, coupled to the barrier layer;
a second control region, of a metal material, extending on the first control region, directly coupled with the first control region.

3. The HEMT device according to claim 2, wherein the first control region is of a same material as the second conductive region.

4. The HEMT device according to claim 1, further comprising:
a second control terminal extending completely above the barrier layer and coupled to the surface of the barrier layer;
wherein:
the first control terminal is interposed between the first conduction terminal and the second control terminal,
the second control terminal is interposed between the first control terminal and the second conduction terminal,
and the second conduction terminal includes:
a third conductive region coupled to the channel layer and forming an ohmic contact with the channel layer;
a fourth conductive region of the semiconductor material having P-type electrical conductivity, extending completely above the barrier layer and coupled to the surface of the barrier layer and with the third conductive region;
wherein the third conductive region is interposed between the second control terminal and the fourth conductive region.

5. The HEMT device according to claim 4, wherein the fourth conductive region is of a same material as the second conductive region.

6. The HEMT device according to claim 4, wherein the second control terminal includes:
a third control region, of the semiconductor material having P-type conductivity, extending on the surface of the barrier layer, in electrical contact with the barrier layer;
a fourth control region, of metal material, extending on the third control region in direct electrical contact with the second control region.

7. The HEMT device according to claim 6, wherein the third control region is of a same material as the second conductive region.

8. The HEMT device according to claim 1, wherein the first conductive region and the second conduction terminal extend through part of the heterostructure, in direct physical and electrical contact with the channel layer.

9. The HEMT device according to claim 1, wherein the first conductive region and the second conduction terminal extend through part of the heterostructure, ending within the barrier layer.

10. The HEMT device according to claim 1, wherein the first conductive region and the second conduction terminal extend on the surface of the barrier layer, directly coupled to the surface of the barrier layer.

11. A method of manufacturing a HEMT device comprising:
forming a buffer layer having N-type electrical conductivity on a substrate;
forming a heterostructure on the buffer layer, including:
forming, on the buffer layer, a channel layer configured to accommodate, in use, a conductive channel of the HEMT device; and
forming a barrier layer on the channel layer;
forming a first control terminal completely above the barrier layer coupled to a surface of the barrier layer;
forming a first conduction terminal at least in part on the barrier layer;
forming a second conduction terminal at least in part on the barrier layer,
wherein the forming the first conduction terminal includes:
forming a first conductive region coupled to the channel layer and forming an ohmic contact with the channel layer;
forming a second conductive region, of a first semiconductor material having P-type electrical conductivity, completely above the barrier layer and coupled to the surface of the barrier layer and with the first conductive contact region,
wherein the forming the first conductive region includes forming the first conductive region between the first control terminal and the second conductive region,
wherein the first conductive region including a first portion extending into the barrier layer, a first space in the first portion, and a second portion on the heterostructure extending transverse to the first portion.

12. The manufacturing method of a HEMT device according to claim 11, wherein the forming the first control terminal includes:
forming a first control region, of a second semiconductor material having P-type conductivity, on the surface of the barrier layer and coupled to the barrier layer;
forming a second control region, of a metal material, on the first control region and in direct electrical contact with the first control region.

13. The manufacturing method of a HEMT device according to claim 12, wherein the forming the first control region is performed concurrently with the forming the second conductive region, and wherein the first control region is of a same material as the second conductive region.

14. The manufacturing method of a HEMT device according to claim 11, further comprising:
forming a second control terminal completely above the barrier layer and coupled to the surface of the barrier layer,
wherein:
the first control terminal is formed between the first conduction terminal and the second control terminal,
the second control terminal is formed between the first control terminal and the second conduction terminal,
and the forming the second conduction terminal includes:
forming a third conductive region coupled to the channel layer and defining an ohmic contact with the channel layer;
forming a fourth conductive region, of a second semiconductor material having P-type electrical conductivity, completely above the barrier layer and coupled to the surface of the barrier layer and with the third conductive region,
wherein the third conductive region is formed between the second control terminal and the fourth conductive region.

15. The manufacturing method of a HEMT device according to claim 14, wherein the forming the second control terminal includes:
forming a third control region, of a third semiconductor material having P-type conductivity, on the surface of the barrier layer, coupled to the barrier layer; and
forming a fourth control region, of a metal material, on the third control region directly coupled to the second control region,
wherein the forming the third conductive region and the third control region are performed concurrently with the forming the second conductive region,
and wherein the fourth conductive region and the third control region are of a same material as the second conductive region.

16. A device, comprising:
a substrate;
a heterostructure on the substrate;
a passivating layer on the heterostructure;
a first control terminal entirely above the barrier layer along a first direction and coupled to a surface of the barrier layer;
a first conduction terminal extending into the heterostructure along the first direction, the first conduction terminal including:
a first conductive region forming an ohmic contact with the channel layer, the first conductive region including a first portion extending into the heterostructure along the first direction and a second portion extending on a first surface of the passivating layer along a second direction transverse to the first direction; and
a second conductive region completely above the barrier layer along the first direction and coupled to the surface of the barrier layer and with the first conductive region.

17. The device according to claim 16, wherein the heterostructure includes a channel layer, configured to accommodate, in use, a conductive channel of the HEMT device, and a barrier layer on the channel layer.

18. The device according to claim 16, wherein the first portion of the first conduction terminal is U-shaped.

19. The device according to claim 16, further comprising a second conduction terminal extending at least in part on the barrier layer.

20. The device according to claim 16, wherein the first conductive region is between the first control terminal and the second conductive region along the second direction.
